(19) United States
(12) Patent Application Publication
(10) Pub. No.: US 2026/0011579 A1
(43) Pub. Date: Jan. 8, 2026

(54) WET ETCHING SYSTEM FOR SEMICONDUCTOR SUBSTRATES

(71) Applicant: Yield Engineering Systems, Inc., Fremont, CA (US)

(72) Inventors: Louis Navarro, Canyon Country, CA (US); Phillip Holmes, Westford, MA (US); Venugopal Govindarajulu, Lehi, UT (US); Hratch Mouradian, Porter Ranch, CA (US); Sossan Wali, Moorpark, CA (US); Hunter Braverman, Newbury Park, CA (US)

(73) Assignee: Yield Engineering Systems, Inc., Fremont, CA (US)

(21) Appl. No.: 18/765,916

(22) Filed: Jul. 8, 2024

(51) Int. Cl. H01L 21/67

(52) U.S. Cl. CPC H01L 21/67086; H01L 21/67023

(57) ABSTRACT

A wet etching system includes a process tank having an inclined tank floor. A drain port is provided at the lower-most location of the inclined tank floor and one or more outlet ports are provided on the inclined tank floor at a location higher than the drain port. The drain port is configured to drain etchant from the tank through a debris-removal system, and the outlet ports are configured to drain the etchant from the tank through a recirculation system.

### TECHNICAL FIELD

The present disclosure relates to devices and methods for wet etching of semiconductor substrates.

### BACKGROUND

In semiconductor high-volume manufacturing (HVM), wet etching systems are commonly used for patterning and structuring substrates such as, for example, glass panels, to create vias, holes, or other features required for semiconductor devices. These wet etching systems are typically specialized equipment designed to etch glass substrates with high precision and throughput. The wet etching process relies on chemical solutions (or etchants) to selectively remove material from the glass substrate. A chemical delivery system is used to store, mix, and deliver the etchant solutions to the etching chamber (called a process tank). The process tank is where actual etching of the glass substrate takes place. The process tank may be equipped with features such as temperature control, agitation mechanisms, and gas exhaust systems.

The glass substrates to be etched are loaded into the process tank, where they are exposed to the etchant solution under controlled conditions. In some applications, a laser etching process is used for initial via formation on glass substrates. The laser ablates the glass to form the desired via structure. The laser etching process often leaves behind molten glass or particulate debris as residue, and micro-cracks around the edges of the vias. To dissolve or otherwise remove this residue and smooth the via sidewalls, the glass substrate is subjected to a wet etching process after laser etching. The etchant penetrates and further etches the vias created by the laser, helping to smooth the sidewalls and remove debris. During wet etching, larger chunks of glass (plugs) or smaller debris from the initial laser process can be dislodged and removed. These glass plugs can sometimes remain in the etching solution and settle to the bottom of the process tank during the etching process. Typically, these glass plugs are removed during periodic preventive maintenance (PM). Since PM typically occurs at scheduled intervals, the process tank may accumulate a substantially quantity of the glass plugs (before they are removed for disposal) degrading the etching efficiency and lifespan of the process tank.

The wet etching systems and methods of the current disclosure may alleviate at least some of the above-described issues.

### SUMMARY

Several embodiments of devices and methods for wet etching of semiconductor substrates are disclosed. It is to be understood that both the foregoing general description and the following detailed description are exemplary and explanatory only. As such, the scope of the disclosure is not limited solely to the disclosed embodiments. Instead, it is intended to cover such alternatives, modifications and equivalents within the spirit and scope of the disclosed embodiments. Persons skilled in the art would understand how various changes, substitutions and alterations can be made to the disclosed embodiments without departing from the spirit and scope of the disclosure.

In one embodiment, a wet etching system is disclosed. The system includes a process tank configured to contain an etchant and includes an inclined tank floor. A drain port may be provided at a lower-most location of the inclined tank floor, and one or more outlet ports may be provided on the inclined tank floor at a location higher than the drain port. The drain port may be configured to drain the etchant from the tank through a debris-removal system and the one or more outlet ports may be configured to drain the etchant from the tank through a recirculation system.

In another embodiment, a wet etching system is disclosed. The wet etching system includes a process tank configured to contain an etchant and an inclined tank floor having an angle of inclination between X and Y degrees. A drain port may be provided at a lower-most location of the inclined tank floor, and one or more outlet ports may be provided on the inclined tank floor at a location higher than the drain port. A first valve may close the drain port. The first valve may be configured to open to drain the etchant in the tank through a debris-removal system. The debris-removal system may be configured to separate solid debris resulting from etching a substrate in the process tank from the etchant passing therethrough. A second valve may close an outlet port of the one or more outlet ports. The second valve may be configured to open to drain the etchant from the tank through a recirculation system. The recirculation system may be configured to treat the etchant passing therethrough and return the treated etchant to the process tank.

### BRIEF DESCRIPTION OF THE DRAWINGS

The accompanying drawings, which are incorporated in and constitute a part of this disclosure, illustrate exemplary embodiments and, together with the description, are used to explain the disclosed principles. In these drawings, where appropriate, reference numerals illustrating like structures, components, materials, and/or elements in different figures are labeled similarly. It should be noted that the figures only depict some exemplary embodiments of the current disclosure and there can be many variations. The figures illustrate embodiments used to describe some features of the current disclosure. It is understood that various combinations of the structures, components, and/or elements, other than those specifically shown, are contemplated and are within the scope of the present disclosure. Specifically, the scope of the current disclosure is defined by the claims and not by the specific embodiments illustrated in the figures.

For simplicity and clarity of illustration, the figures depict the general structure of the various described embodiments. Details of well-known components or features may be omitted to avoid obscuring other features, since these omitted features are well-known to those of ordinary skill in the art. Further, elements in the figures are not necessarily drawn to scale. The dimensions of some features may be exaggerated relative to other features to improve understanding of the exemplary embodiments. One skilled in the art would appreciate that the features in the figures are not necessarily drawn to scale and, unless indicated otherwise, should not be viewed as representing proportional relationships between features in a figure. Additionally, even if it is not specifically mentioned, aspects described with reference to one embodiment or figure may also be applicable to, and may be used with, other embodiments or figures.

FIG. 1 is a schematic representation of an exemplary wet etching system of the current disclosure;

FIGS. 2A-2C are schematic illustrations of the top view of an exemplary process tank of FIG. 1, consistent with some embodiments of the current disclosure;

FIGS. 3A-3B are schematic illustrations of the bottom surface of an exemplary process tank of FIG. 1, consistent with some embodiments of the current disclosure;

FIGS. 4A-4B are schematic illustrations of an exemplary process tanks of FIG. 1, consistent with some embodiments of the current disclosure; and

FIG. 5 is a flowchart of an exemplary wet etching process, consistent with some embodiments of the current disclosure.

### DETAILED DESCRIPTION

All relative terms such as “about,” “substantially,” “approximately,” etc., indicate a possible variation of +10% (unless noted otherwise or another variation is specified). For example, a feature disclosed as being about “t” units long (wide, thick, etc.) may vary in length from (t−0.1t) to (t+0.1t) units. Similarly, a temperature within a range of about 100-150° C. can be any temperature between (100-10%) and (150-10%). In some cases, the specification also provides context to some of the relative terms used. For example, a structure described as being substantially linear or substantially planar may deviate slightly (e.g., 10% variation in diameter at various locations, etc.) from being perfectly linear. Further, a range described as varying from, or between, 5 to 10 (5-10), includes the endpoints (i.e., 5 and 10).

Unless otherwise defined, all terms of art, notations, and other scientific terms or terminology used herein have the same meaning as is commonly understood by one of ordinary skill in the art to which this disclosure belongs. Some of the components, structures, and/or processes described or referenced herein are well understood and commonly employed using conventional methodology by those skilled in the art. Therefore, these components, structures, and processes will not be described in detail. All patents, applications, published applications and other publications referred to herein as being incorporated by reference are incorporated by reference in their entirety. If a definition or description set forth in this disclosure is contrary to, or otherwise inconsistent with, a definition and/or description in these references, the definition and/or description set forth in this disclosure controls over those in the references that are incorporated by reference. None of the references described or referenced herein is admitted as prior art to the current disclosure.

The term substrate refers to the base material on which semiconductor or photonic devices or circuits are fabricated. In the discussion below, the term “substrate” is used broadly to refer to any component having a relatively flat surface upon which structures of semiconductor devices or photonic devices may be created. For example, as used herein, a substrate includes a plate, a panel (e.g., a glass panel used in LCD or semiconductor manufacturing, photomask manufacturing, etc.), a semiconductor wafer (e.g., a silicon wafer used to fabricate IC devices), a wafer with multiple IC devices formed thereon, a single IC device, a part (e.g., ceramic, organic, metallic, etc.) with one or more coatings formed or disposed thereon, etc.

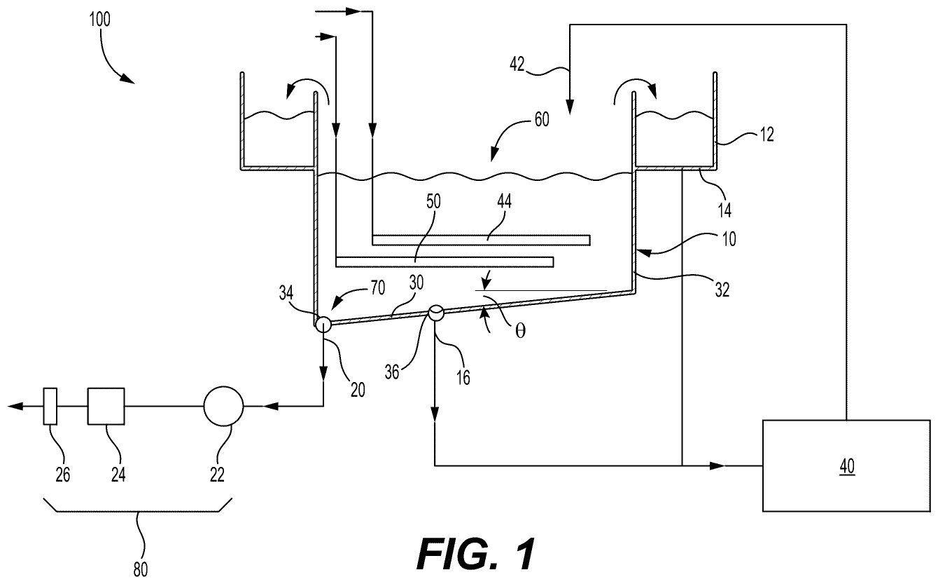

FIG. 1 is a schematic representation a wet etching system 100 that may be used to etch semiconductor substrates. In the discussion below, etching of glass substrates using system 100 will be described. Wet etching system 100 includes a process tank 10 that is configured to receive one or more glass substrates (not shown) and a chemical solution (e.g., a chemical etchant 60) that is adapted to etch the glass substrate. The shape and size of the tank 10 can vary depending on the specific application and the dimensions of the substrates. Although not a requirement, tank 10 may have a rectangular, square, or a cylindrical shape. Regardless of its shape and size, tank 10 may have a volume, bounded by sidewalls 32 and a bottom surface 30 (or tank floor), that contains the etchant 60.

Tank 10 may be made from materials that are resistant to the chemical etchant 60. Common materials include high-density polyethylene (HDPE), polypropylene (PP), polyvinyl chloride (PVC), and stainless steel (with or without appropriate coatings). In some embodiments, Teflon PFA may be a preferred material for tank 10 since it can support a variety of chemicals and process conditions (e.g., temperature ranges). Tank 10 may contain (or may be filled with) the etchant 60 that is configured to etch the substrate. For example, potassium hydroxide (KOH) or hydrofluoric acid (HF) may be used for etching glass, ferric chloride (FeCl₃) or cupric chloride (CuCl₂) may be used for etching metals like copper, etc. In some embodiments, sodium hydroxide (NaOH) (at high temperatures in some cases) may be a preferred etchant 10. The etchant 60 may be recirculated through tank 10. Pumps and/or circulators of system 100 may circulate the etchant within the tank 10 and through external filters and other treatment systems (heaters, etc.) of a recirculation system 40 to maintain consistency (e.g., PH level) and remove particulate debris. System 100 may also include flow control devices, such as, flow meters and valves, to ensure proper concentration and flow rates of the etchant 60 through the tank 10.

Gas (e.g., nitrogen gas) bubbles may be introduced into the etchant 60 in tank 10 through a bubbler or a nitrogen sparger 44 to create agitation and improve etching uniformity. A nitrogen sparger works by injecting nitrogen gas into the etchant 60 through a series of small openings or injection points. The nitrogen bubbles rise to the surface and transfer their buoyancy to the etchant 60 thereby promoting mixing of the etchant 60. Alternatively, or additionally, in some embodiments, mechanical agitators (such as, e.g., impellers or paddles) may be used to ensure uniform distribution of the etchant 60 in the tank 10. Tank 10 may also include a water sparger 50 configured to direct water (e.g., de-ionized (DI) water) into tank 10. In some embodiments, water sparger 50 may direct water (e.g., DI water) under pressure to the floor (bottom surface 30) of the tank 10. This high-pressure water from sparger 50 may be used to sweep the floor (e.g., move debris on the tank floor) of the tank.

Although not shown in FIG. 1, in some embodiments, tank 10 may include submersible heaters or external heating jackets adapted to maintain the etchant 60 at a desired temperature. Thermocouples (or other temperature sensors) may monitor the etchant temperature, and controllers may adjust the heating elements to maintain temperature control. Smaller tanks 10 might allow for manual loading and unloading of substrates, for example, using baskets or racks. Larger tanks 10 may include automated loading systems (e.g., conveyor systems, robotic arms, or hoists) to move substrates in and out of the tank 10.

The etchant 60 may circulate or move in the tank 10 from the bottom of the tank towards its top and overflow into a weir 12 formed around the sidewalls 32. From the weir 12, the etchant 60 may be directed out of the tank 10 through an outlet port 14 to the recirculation system 40. Among other mechanisms/devices, the recirculation system 40 may include a collection tank (or reservoir) that collects of stores the drained etchant from tank 10, a mechanism to add fresh etchant or replenish the reactive species in the etchant 60 that may be consumed during the etching process (e.g., dilution or addition of concentrated solutions), filters (e.g., mesh filters, cartridge filters, bag filters, etc.) to remove particulates, contaminants, and reaction byproducts, sensors (e.g., pH sensors, etc.) to measure the chemical purity (of the etchant, devices (e.g., heaters, heat exchangers, etc.) that helps maintain uniform etchant temperature.

After rejuvenation of the etchant 60 in the recirculation system 40, it is directed back into the tank 10 via an inlet port 42. Recirculation system 40 may also include pumps and flow control devices that are configured to circulate the rejuvenated etchant back to tank 10. Since recirculation systems that may be used with wet etching systems 100 are known in the art, they are not described in more detail herein. By continuously removing a portion of the etchant 60 from the tank 10 and replenishing it or replacing it with fresh etchant, the wet etching system 100 helps to maintain a consistent chemical concentration of the etchant 60 throughout the etching process.

In some embodiments, weir 12 may include liquid level sensors (high/low level sensors) and thermocouples to monitor and maintain the quantity and temperature of the etchant 60 in tank 10. In addition to the outlet port 14 in weir 12, one or more outlet ports 16 may also be provided in the bottom region (e.g., on the bottom surface 30) of the tank 10. Although a single outlet port 16 is illustrated, in some embodiments multiple outlet ports 16 may be provided. Outlet port 16 may include a valve 36 (e.g., a ball valve, not shown) that is configured to selectively direct the etchant 60 out of the tank 10. For example, opening the valve coupled to outlet port 16 may drain the etchant out of the tank 10. The drained etchant may be directed to the recirculation system 40 for rejuvenation before being stored or directed back into tank 10 via inlet port 42.

With continued reference to FIG. 1, in wet etching systems of the current disclosure, the bottom surface 30 of tank 10 (or the tank floor) is sloped or inclined to facilitate the efficient collection and removal of debris and particulates (e.g., glass plugs) that accumulate in the etchant 60 during the etching process. The inclined bottom surface 30 naturally directs glass plugs, particles, or by-products (collectively referred to herein as “debris”) towards the lowest point (or a collection area 70) of the tank 10. Gravity helps in this process, causing the heavier particles to settle and slide down the inclined surface towards the collection area 70. As the etchant 60 flows over the inclined bottom surface 30 of the tank 10, it helps to sweep the debris towards the collection area 70. The inclination of the bottom surface 30 ensures that debris are not allowed to settle uniformly across the tank bottom, but instead are directed to a specific area (e.g., collection area 70) for collection.

In embodiments of the current disclosure, the angle of inclination (0) of the bottom surface 30 is designed to be steep enough to allow the debris to slide down easily but not so steep as to interfere with the tank's stability or the flow of the etchant 60. In general, the angle of inclination (θ) may be greater than or equal to (≥) about 4 degrees. In some embodiments, angle θ may be between about 4-15 degrees, while in some embodiments, angle θ may be between about 10-15 degrees, while in some embodiments, angle θ may be between 4-6 degrees. The bottom surface 20 may be configured to minimize resistance to particle movement and to prevent (or minimize) debris from getting stuck as it slides towards the collection area 70.

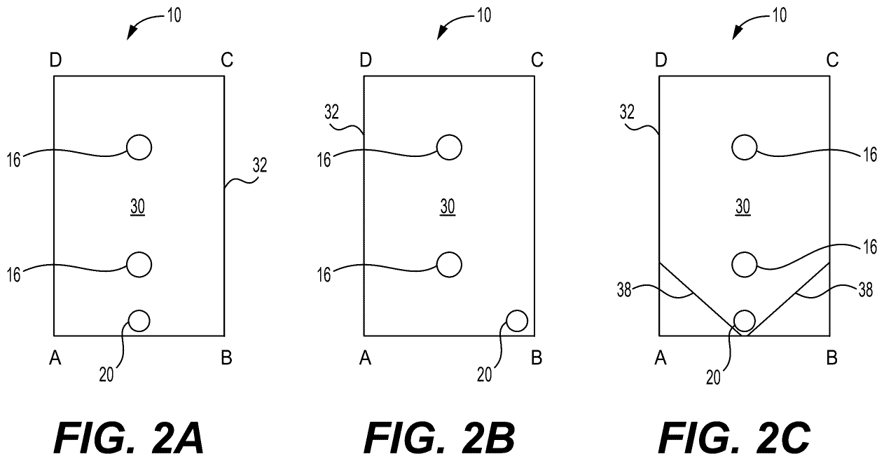

FIGS. 2A-2C are schematic illustrations of the top view of an exemplary tank 10 in different embodiments. In some embodiments, the bottom surface 30 of tank 10 inclines from one side surface of the tank 10 to the opposite side surface. For example, with reference to FIG. 2A, the bottom surface 30 may be inclined (e.g., by an angle θ) from side CD to side AB. With reference to FIG. 2B, in some embodiments, the bottom surface 30 may incline towards one corner (e.g., corner B) of tank 10. The collection area 70 may be located at the lowest point (or proximate to the lowest point) of tank 10. For example, when the bottom surface 30 inclines from side CD to side AB (see FIG. 2A), the collection area 70 may be located at some location on side AB (e.g., at the center of side AB, at or proximate corner A, at or proximate corner B, etc.). Similarly, when the bottom surface 30 inclines towards one corner (e.g., corner B), the collection area 70 may be located at or proximate that corner.

The collection area 70 of the tank 10 includes a suction port or a drain port 20 with a ball valve 34 (or another type of valve or gate) that may be selectively opened to remove the debris collected in the collection point. Drain port 20 may be positioned at (or positioned proximate to) the lowest point of the inclined bottom surface 30 to take advantage of gravity for efficient collection and removal of debris. By concentrating the debris at a single location of the tank floor (e.g., collection area 70), it becomes easier to remove it via drain port 20. In some embodiments, a suction device (e.g., a pump, etc.) may be fluidly coupled to the drain port 20 such that the drain port removes the debris using suction. The drain port 20 may be connected to a suction line that leads to a pump or a vacuum system. Suction may assist in drawing out the debris from tank 10. Although not shown in FIG. 1, in some embodiments, a gutter, sump, or a collection area may be provided at the collection area 70 to collect the accumulated debris prior to removal via the drain port 20.

Accumulation of debris in the tank 10 can contaminate the etchant 60 and negatively affect etching quality and consistency. An inclined tank floor (i.e., bottom surface 30) helps in promptly removing these debris, maintaining the purity and effectiveness of the etchant 60. Debris-free etchant 60 in the tank 10 ensures that the etching process remains consistent across all substrates (or regions of a single substrate). Moreover, the inclined bottom surface 30 helps to prevent the debris from exiting through the outlet port 16 of the recirculation system 40 and clogging the outlet or the filtration systems of the recirculation system 40. This ensures a smooth recirculation of the etchant 60 through the tank 10 and reduces the risk of operational disruptions.

In general, the bottom surface 20 may be configured to promote movement (e.g., sliding) of debris towards the collection area 70. In some embodiments, the bottom surface 30 may be a flat and smooth surface on which debris may slide easily towards the collection area 70. In some cases, debris removal efficiency may depend on the water pressure from DI water sparger 50 that is used to sweep over a smoother surface at some inclination. Typically, the less the inclination (angle θ), more water pressure may be desired and vice versa. However, it is also contemplated that, in some embodiments, the bottom surface 30 may be textured to assist in directing the flow of debris towards the collection area 70. In some embodiments, as illustrated in FIG. 2C, guide plates, baffles, or deflector 38 may be strategically placed on the bottom surface 30 to direct the flow of debris towards the collection area 70.

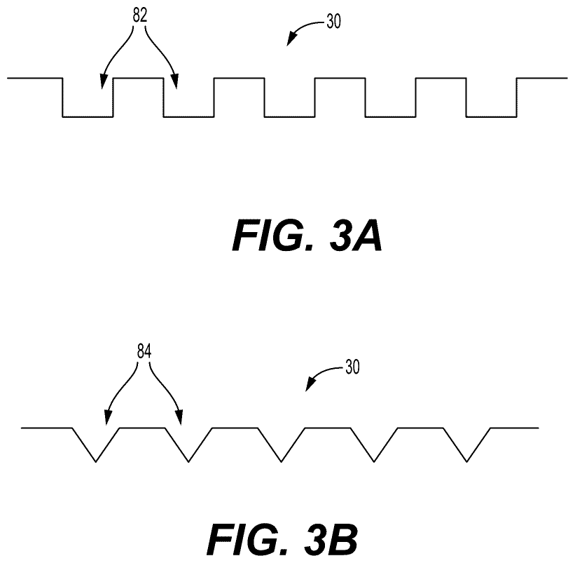

In some embodiments, channels, grooves, or other similar features may be provided on the bottom surface 30 to aid the debris in sliding towards the collection area 70. For example, these features may converge towards the collection area 70 such that the sliding debris selectively flows or slides in that direction. In some embodiments, these features may be linear structures that are integrated into the tank floor to help guide the particulates efficiently. FIGS. 3A and 3B illustrate some exemplary features that may be provided on the bottom surface 30 of tank 10 in different embodiments. FIG. 3A illustrates rectangular channels or grooves 82 formed on the bottom surface 30, and FIG. 3B illustrate V-shaped grooves 84. These features are merely exemplary, and in general, any type of features that assist in guiding the debris towards the collection area 70 may be provided on the tank floor. It is also contemplated that, in some embodiments, jets or nozzles may be used to create a directed flow of the etchant solution on the tank floor and push the debris towards the collection area 70.

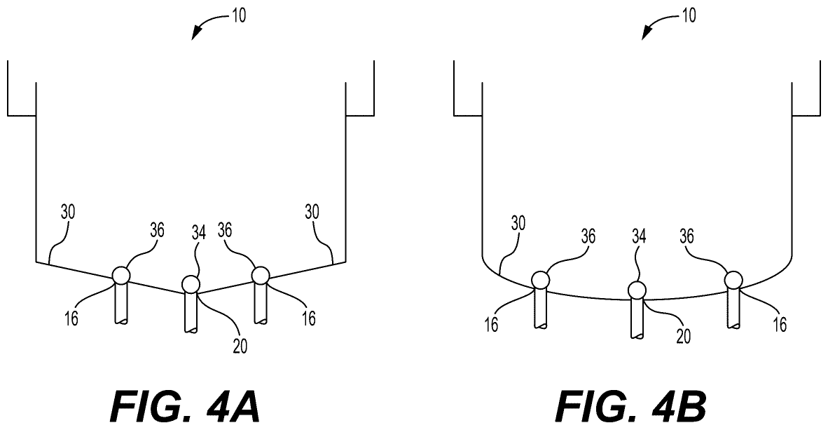

Although a tank floor formed of a single inclined bottom surface 30 is described, this is only exemplary. In some embodiments, as illustrated in FIG. 4A, the tank floor may be formed of a pair of inclined surfaces that converge towards a collection area 70 with a drain port 20 in the middle. In some embodiments, the tank floor of an exemplary tank may include multiple pairs of inclined bottom surfaces that converge towards a single collection area 70. For example, in a rectangular tank with a pair of opposite side surfaces, a pair of inclined bottom surfaces may converge from each pair of opposite side surfaces towards a common collection area 70 with a drain port 20 at the center. In some embodiments, as illustrated in FIG. 4B, the bottom surface 30 of an exemplary tank may be curved with the collection area 70 formed at its lower-most point at the center. In some such embodiments, the curved bottom surface 30 may include helical or radial channels that converge towards the central drain port 20. In each of these cases, the collection area 70 with the drain port 20 (that removes the debris) is disposed on the lowest point (or region) of the tank floor and the outlet ports 16 are disposed at locations (of the tank floor) higher than the drain port 20, and debris on the tank floor slides on the inclined bottom surface 30 towards the collection area 70.

Referring back to FIG. 1, the drain port 20 may be connected to a debris-removal system 80 configured to separate the debris from the debris-laden etchant removed from the tank 10 via the drain port 20. In some exemplary embodiments, the debris-removal system 80 may include a centrifugal pump 22 to move the debris-laden etchant through one or more filters 24 and one or more sensors (e.g., a pH sensor 26). The filter(s) 24 may be configured to separate the debris from the etchant for disposal. In general, the centrifugal pump 22 and the filter(s) 24 may be configured to withstand the debris-laden etchant flowing through them. For example, in some embodiments, the centrifugal pump 22 and the filter(s) may be made of, or housed in, stainless or another suitable wear-resistant material. In some embodiments, nets or other filters may be provided between the tank 10 and the pumps (e.g., the pump of the debris-removal system 80 and/or recirculation system 40) to ensure that large-sized debris are captured before they enter the pump and/or other components. It should be noted that the specific components of the debris-removal system 80 illustrated in FIG. 1 and described above are only exemplary. In general, the debris-removal system 80 may include components that are configured to separate and remove the debris from the debris-laden liquid removed from the tank 10.

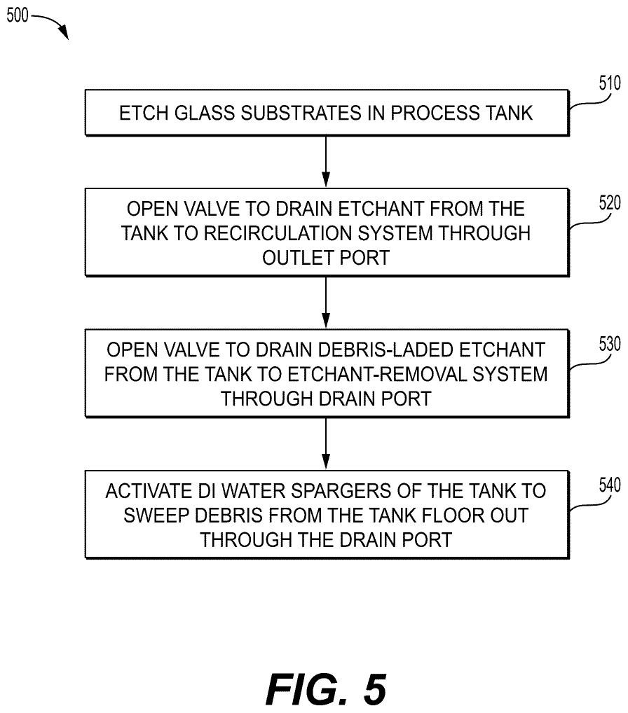

FIG. 5 is a flow chart of an exemplary process of using the disclosed wet etching system 100. In step 510, etching of one or more glass substrates is carried out in tank 10. During the etching process, etchant 60 in the tank may be recirculated through the recirculation system 40. At the end of the etching process, in step 520, the valves of the inlet port 16 are opened to drain the etchant 60 from the tank 10 to the recirculation system 40 leaving a small amount of debris-laden etchant at the bottom of the sloped tank 10. In step 530, the ball valve 34 that closes drain port 20 is opened to drain the debris-laden etchant from the tank 10 to the debris-removal system 80. In step 540, the DI water sparger 50 is activated to sweep any debris stuck to the inclined bottom surface 30 of the tank 10 out through the drain port 20. Meanwhile, in the debris-removal system 80, the pump 22 moves the debris-laden etchant through the filter(s) 24. In some embodiments, the DI water flow through sparger 50 and the pump 22 may continue to run until the sensor 26 indicates a desired reading (e.g., that all the etchant is drained from the tank 10). In some embodiments, after a preset amount of time, the flow of DI water and the pump 22 may turn off and the ball valve 34 may close. The process recirculation may then turn on to refill the tank 10 for etching the next lot of glass substrates. Filter(s) 24 of the debris-removal system 80 may be cleaned out as part of a PM or may be dissolved by passing a sufficient amount of etchant therethrough.

It should be noted that the process 500 described with reference to FIG. 5 is only exemplary. Moreover, the illustrated steps need not be performed in the illustrated order. For example, some steps may be performed before or along with other steps, some steps may be eliminated, and/or other steps may be added. As one example, in some embodiments, steps 530 and 540 may be performed simultaneously. As another example, in some embodiments, step 540 may be eliminated. In general, a person of ordinary skill in the art would recognize that although exemplary embodiments of wet etching systems, process tanks, and wet etching processes are described, the scope of the current disclosure encompasses many variations. Furthermore, although the process of etching glass substrates and the removal of glass debris is described, embodiments of the current disclosure may be used to etch any type of substrate used in semiconductor fabrication.

What is claimed is:

1. A wet etching system, comprising:
a process tank configured to contain an etchant, wherein the process tank includes an inclined tank floor;
a drain port provided at a lower-most location of the inclined tank floor; and
one or more outlet ports provided on the inclined tank floor at a location higher than the drain port, wherein the drain port is configured to drain the etchant from the tank through a debris-removal system and the one or more outlet ports are configured to drain the etchant from the tank through a recirculation system.

2. The wet etching system of claim 1, wherein the tank floor includes one or more inclined bottom surfaces.

3. The wet etching system of claim 1, wherein an angle of inclination of the tank floor is between X and Y degrees.

4. The wet etching system of claim 1, wherein the angle of inclination is between X1 and Y1 degrees.

5. The wet etching system of claim 1, wherein the drain port is closed by a valve that is configured to open to drain the etchant through the debris-removal system.

6. The wet etching system of claim 1, wherein each of the one or more outlet ports is closed by a valve that is configured to open to drain the etchant through the recirculation system.

7. The wet etching system of claim 1, wherein the debris-removal system includes one or more filters configured to separate solid debris resulting from etching a substrate in the process tank from the etchant passing therethrough.

8. The wet etching system of claim 7, wherein the debris-removal system further includes a centrifugal pump configured to move the etchant drained through the drain port through the one or more filters.

9. The wet etching system of claim 1, wherein the recirculation system is configured to treat the etchant passing therethrough and return the treated etchant to the process tank.

10. The wet etching system of claim 1, wherein the inclined tank floor includes one or more features configured to assist in movement of solid debris resulting from etching a substrate in the process tank towards the drain port.

11. The wet etching system of claim 1, wherein the inclined tank floor includes multiple inclined bottom surfaces that converge towards the drain port.

12. The wet etching system of claim 1, further including a de-ionized water sparger positioned in the process tank and configured to spray de-ionized water on the inclined tank floor.

13. The wet etching system of claim 1, further including a nitrogen sparger positioned in the process tank.

14. A wet etching system, comprising:
a process tank configured to contain an etchant, wherein the process tank includes an inclined tank floor having an angle of inclination between X and Y degrees;
a drain port provided at a lower-most location of the inclined tank floor;
one or more outlet ports provided on the inclined tank floor at a location higher than the drain port;
a first valve closing the drain port, wherein the first valve is configured to open to drain the etchant in the tank through a debris-removal system, and wherein the debris-removal system is configured to separate solid debris resulting from etching a substrate in the process tank from the etchant passing therethrough; and
a second valve closing an outlet port of the one or more outlet ports, wherein the second valve is configured to open to drain the etchant from the tank through a recirculation system, and wherein the recirculation system is configured to treat the etchant passing therethrough and return the treated etchant to the process tank.

15. The wet etching system of claim 14, wherein the angle of inclination of the tank floor is between X1 and Y1 degrees.

16. The wet etching system of claim 14, wherein the inclined tank floor includes multiple inclined bottom surfaces that converge towards the drain port.

17. The wet etching system of claim 14, wherein the inclined tank floor includes one or more features configured to assist the movement of the solid debris towards the drain port.

18. The wet etching system of claim 14, wherein the inclined tank floor includes multiple inclined bottom surfaces that converge towards the drain port.

19. The wet etching system of claim 14, further including a de-ionized water sparger positioned in the process tank and configured to spray de-ionized water on the inclined tank floor.

20. The wet etching system of claim 14, wherein the process tank is configured to receive one or more glass substrates and the etchant is configured to etch the one or more glass substrates.
